(19) United States
(12) Patent Application Publication
(10) Pub. No.: US 2015/0255665 A1
(43) Pub. Date: Sep. 10, 2015

(54) LASER HEATING TREATMENT METHOD AND METHOD FOR MANUFACTURING SOLID-STATE IMAGING DEVICE

(71) Applicant: Kabushiki Kaisha Toshiba, Minato-ku (JP)

(72) Inventors: Hiroyuki FUKUMIZU, Yokohama (JP); Yoshio Kasai, Oita (JP); Takaaki Minami, Oita (JP); Kenichi Yoshino, Oita (JP); Yosuke Kitamura, Katsushika (JP); Yusaku Konno, Yokohama (JP); Koichi Kawamura, Yokohama (JP); Satoshi Kato, Oita (JP); Naoaki Sakurai, Yokohama (JP)

(73) Assignee: Kabushiki Kaisha Toshiba, Minato-ku (JP)

(21) Appl. No.: 14/631,002

(22) Filed: Feb. 25, 2015

(30) Foreign Application Priority Data
Mar. 7, 2014 (JP) 2014-044723

(51) Int. Cl. H01L 31/18; H01L 27/146

(52) U.S. Cl. CPC H01L 31/1864; H01L 27/14685; H01L 27/14623

(57) ABSTRACT

According to one embodiment, a laser heating treatment method includes forming a film having a higher melting point than a structural body provided on a substrate so as to cover the structural body, and heating the structural body by irradiating the film and the structural body with laser.

### CROSS-REFERENCE TO RELATED APPLICATIONS

This application is based upon and claims the benefit of priority from the Japanese Patent Application No. 2014-044723, filed on Mar. 7, 2014; the entire contents of which are incorporated herein by reference.

### FIELD

Embodiments described herein relate generally to a laser heating treatment method and a method for manufacturing a solid-state imaging device.

### BACKGROUND

One method for heating treatment is a method for irradiating a target with laser. Unevenness of a fine pattern may be provided on the target such as a substrate. When such a substrate is subjected to heating treatment, it is desired to perform heating treatment while maintaining the feature of the fine pattern.

### BRIEF DESCRIPTION OF THE DRAWINGS

FIG. 1 is a flow chart illustrating a laser heating treatment method according to a first embodiment;

FIG. 2 illustrates a substrate used in the laser heating treatment method according to the first embodiment;

FIGS. 3A and 3B are reference views illustrating the substrate;

FIG. 4 illustrates a substrate used in the laser heating treatment method according to the first embodiment;

FIG. 5 is a schematic sectional view showing a solid-state imaging device according to a second embodiment;

FIG. 6 is a reference diagram illustrating the relationship between the laser irradiation amount and the dark current;

FIG. 7 is a reference diagram illustrating the relationship between the laser irradiation amount and the sensitivity;

FIGS. 8A to 8D are reference views illustrating the relationship between the laser irradiation amount and the DTI structure;

FIGS. 9A and 9B are reference views illustrating the relationship between the laser irradiation amount and the DTI structure;

FIG. 10 shows the relationship between the laser irradiation amount and the sensitivity in the second embodiment;

FIG. 11 illustrates the relationship between the laser irradiation amount and the DTI structure in a third embodiment;

FIG. 12 illustrates the relationship between the laser irradiation amount and the sensitivity in the third embodiment; and

FIGS. 13A to 13I show a flow chart of part of a process for manufacturing a solid-state imaging device.

### DETAILED DESCRIPTION

According to one embodiment, a laser heating treatment method includes forming a film having a higher melting point than a structural body provided on a substrate so as to cover the structural body, and heating the structural body by irradiating the film and the structural body with laser.

Embodiments of the invention will now be described with reference to the drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In this specification and the drawings, components similar to those described previously with reference to earlier figures are labeled with like reference numerals, and the detailed description thereof is omitted appropriately.

### First Embodiment

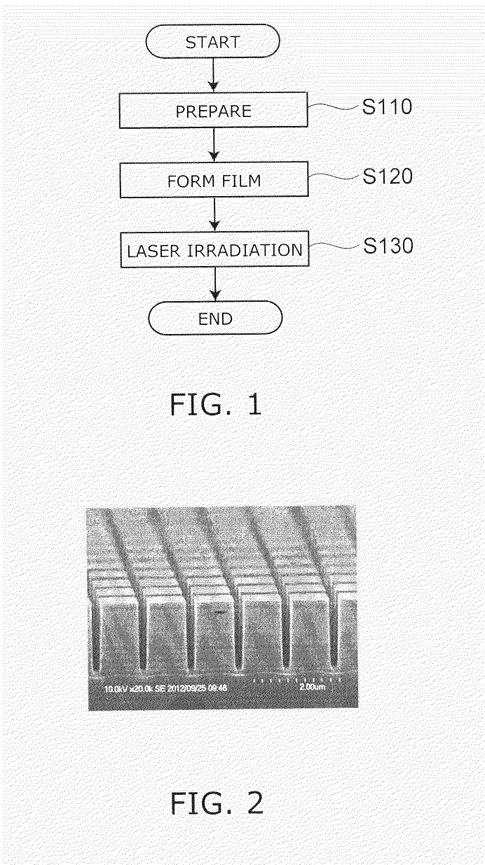

FIG. 1 is a flow chart illustrating a laser heating treatment method according to a first embodiment.

As shown in FIG. 1, a substrate is prepared (step S110). The substrate is e.g. a Si substrate. A structural body is provided on the substrate. An unevenness, for instance, is formed at the surface of the substrate.

A film is formed on the surface of the substrate (step S120). In the case where the substrate is a Si substrate, the film is made of a material having a higher melting point than Si. The film having a higher melting point than the structural body is formed on the substrate so as to cover the structural body. The film is made of a material having a high transmittance for the laser wavelength described later. For instance, the transmittance of the film for the laser wavelength is higher than the transmittance of the structural body for the laser wavelength. The material of the film is e.g. SiO₂, Si₃N₄, or SiON.

The surface of the substrate is irradiated with laser (step S130). The surface of the substrate is heated by irradiation of the surface of the substrate with laser. The structural body is heated by irradiation of the film and the structural body with laser. The laser is e.g. an excimer laser (wavelength: 308 nanometers).

FIG. 2 illustrates a substrate used in the laser heating treatment method according to the first embodiment.

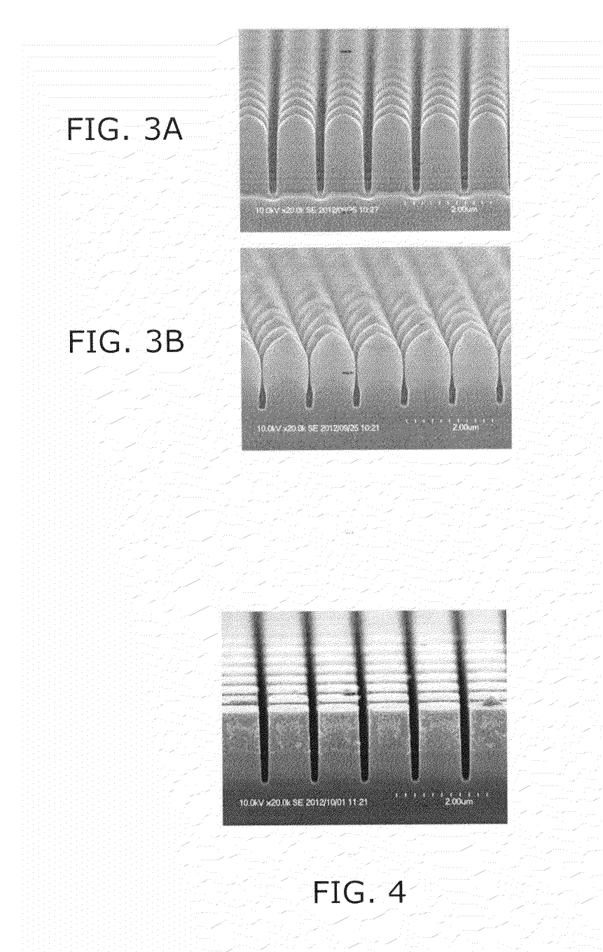

FIGS. 3A and 3B are reference views illustrating the substrate.

FIG. 4 illustrates a substrate used in the laser heating treatment method according to the first embodiment.

FIG. 2 shows the feature of the surface of a Si substrate before being irradiated with laser. FIG. 3A shows the feature of the surface of the Si substrate after the Si substrate is irradiated with laser at an irradiation amount of 1.3 J/cm². FIG. 3B shows the feature of the surface of the Si substrate after the Si substrate is irradiated with laser at an irradiation amount of 2.0 J/cm². FIG. 4 shows the feature of the surface of the Si substrate after the surface of the Si substrate is covered with a SiO₂ film (the inside of the depression is filled with the SiO₂ film) and the Si substrate is irradiated with laser at an irradiation amount of 2.0 J/cm². In FIGS. 3A, 3B, and 4, the surface of the Si substrate having an unevenness shown in FIG. 2 is irradiated with laser.

When the temperature of the surface of the Si substrate increases to above the melting point of Si (1414° C.), the surface of the Si substrate melts. The unevenness formed at the surface of the Si substrate is deformed by the surface tension at the time of melting.

As shown in FIGS. 3A and 3B, the unevenness formed at the surface of the Si substrate is deformed more significantly with the increase of the irradiation amount (irradiation energy) of the laser. In the case where an unevenness is formed at the surface of the Si substrate, the feature of the surface of the Si substrate changes when the Si substrate is heated to above the melting point of Si. In the case where the surface of the Si substrate is flat, no significant change is observed in the feature of the surface of the Si substrate.

In FIG. 4, the Si substrate is irradiated with laser after the Si substrate is covered with a SiO₂ film. Thus, the feature of the unevenness on the Si substrate is not significantly changed.

The surface of the Si substrate is irradiated with laser after being covered with a film (e.g., SiO₂ film) including a material having a higher melting point than Si. Si can be heated to above the melting point of Si without significantly changing the feature of the unevenness formed at the surface of the Si substrate.

The Si substrate with the surface covered with the SiO₂ film is irradiated with laser. The SiO₂ film is transmissive to a wavelength of 308 nanometers (the wavelength of an excimer laser). Thus, the laser light is transmitted through the SiO₂ film. The transmitted laser light is absorbed in the surface of the Si substrate. Thus, Si is heated.

The surface of the Si substrate is covered with a SiO₂ film (melting point: 1650° C.) having a higher melting point than Si. This can suppress melting of Si and changing of the feature of the unevenness. Then, the SiO₂ film can be removed with chemicals such as HF.

The surface of the substrate including a to-be-heated material (e.g., Si) is covered with a material (e.g., SiO₂) having a higher melting point than the to-be-heated material and having high transmittance to laser light. In the case where the surface of the substrate is provided with e.g. an unevenness, the to-be-heated material can be heated to a temperature higher than the melting point of the to-be-heated material without significantly changing the feature of the surface of the substrate.

In this embodiment, a SiO₂ film is formed on the surface of the Si substrate. Then, the surface of the Si substrate having an unevenness is heated by an excimer laser (wavelength: 308 nanometers). Alternatively, the surface of the Si substrate may be covered with a Mo film (the inside of the depression is filled with the Mo film). Then, the surface of the Si substrate having an unevenness may be heated by an excimer laser.

Mo has a low light transmittance for a wavelength of 308 nanometers. Mo has a high light reflectance for a wavelength of 308 nanometers, and absorbs the light. When a Mo film is irradiated with laser light, the surface of the Mo film is heated. Mo has a high thermal conductivity. Thus, the heat absorbed at the surface of the Mo film can be transferred to Si. Mo has a high melting point (2600° C.). Thus, the feature of the surface of the Si substrate is not significantly changed even if the surface of the Si substrate is heated to 1500° C., at which dielectric anomaly of Si occurs.

To remove Mo covering the surface of the Si substrate, Mo is etched with a mixed liquid of concentrated sulfuric acid and concentrated nitric acid.

The laser heating treatment method according to this embodiment is applicable to e.g. a method for manufacturing a solid-state imaging element. For instance, in a solid-state imaging element such as a CCD (charge coupled device) and CMOS (complementary metal-oxide semiconductor) image sensor, a fine pattern including a photoelectric conversion element is formed on a semiconductor substrate. The surface of such a substrate is irradiated with laser to perform heating treatment. Thus, the dark current resulting from e.g. interface levels is decreased. Pixels are miniaturized with the increase in the number of pixels. In a solid-state imaging element having such a structure, it is desired to decrease the dark current and to improve sensitivity. By the laser heating treatment method according to this embodiment, the desired heating treatment can be performed while maintaining the feature of the fine pattern of the substrate.

### Second Embodiment

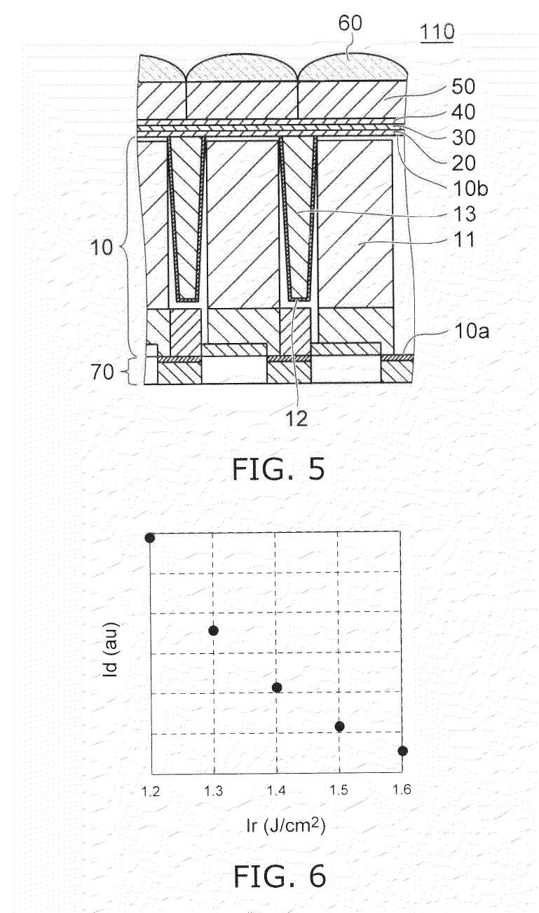

FIG. 5 is a schematic sectional view showing a solid-state imaging device according to a second embodiment.

The solid-state imaging device 110 includes e.g. a semiconductor layer 10, an oxide film 20 formed on a second surface 10b of the semiconductor layer 10, an antireflective film 30 formed on the oxide film 20, a planarization layer 40 formed on the antireflective film 30, a color filter 50 formed on the planarization layer 40, a microlens 60 formed on the color filter 50, and a wiring layer 70 formed on a first surface 10a of the semiconductor layer 10. A support substrate or the like is provided on the wiring layer 70.

The semiconductor layer 10 has a first surface 10a and a second surface 10b. The first surface 10a is a surface on the opposite side from the second surface 10b. In this embodiment, the first surface 10a is a front surface, and the second surface 10b is a back surface. The solid-state imaging device 110 of this embodiment is e.g. a solid-state imaging device of the back irradiation type.

The oxide film 20 is e.g. a silicon oxide film. In the case where the semiconductor layer 10 is a Si-containing layer and the oxide film 20 is a silicon oxide film, a dark current due to interface levels may occur at the interface between Si and SiO₂. A HfO₂ film or a stacked film of HfO₂/SiO₂ may be provided between the semiconductor layer 10 and the oxide film 20 to suppress the occurrence of dark current.

The antireflective film 30 is made of e.g. SiN, SiON, or TaO. The refractive index of SiO₂ to light of a wavelength of 633 nanometers is 1.5. The refractive index of SiN and SiON to light of a wavelength of 633 nanometers is 1.8. The refractive index of TaO to light of a wavelength of 633 nanometers is 2.1. The refractive index of SiN, SiON, and TaO to light of a wavelength of 633 nanometers is higher than the refractive index of SiO₂.

The planarization layer 40 is a layer for planarizing the surface on which the color filter 50 is formed.

The color filters 50 each transmit light in a different wavelength range. The color filters 50 include e.g. an R color filter for transmitting light in the red wavelength range, a G color filter for transmitting light in the green wavelength range, and a B color filter for transmitting light in the blue wavelength range.

The microlens 60 condenses light incident from a light source and guides the light to the second surface 10b (back surface) side of the semiconductor layer 10.

The wiring layer 70 includes an insulating layer and a wiring formed in the insulating layer. The wiring layer 70 includes e.g. a circuit for reading a signal. The wiring layer 70 reads the charge accumulated in the light reception section 11 described later.

The semiconductor layer 10 is an epitaxial layer formed on a semiconductor substrate such as a Si substrate. A light reception section 11, an intermediate layer 12, and a light blocking film 13 are provided in the semiconductor layer 10. The film thickness of the semiconductor layer 10 is e.g. approximately 4 micrometers.

The light reception section 11 corresponds to a pixel region including a photodiode PD. The light reception section 11 is e.g. an n-type Si layer. The light reception section 11 converts light to a signal and accumulates charge. The light is applied in the direction from the microlens 60 toward the semiconductor layer 10.

The light blocking film 13 is formed between the light reception sections 11 (pixel regions). The light blocking film 13 isolates the adjacent light reception sections 11. The light blocking film 13 is in contact with the oxide film 20. An opening (depression) may be formed between the light reception sections 11 (pixel regions), and the light blocking film 13 may be embedded in the opening. This structure is referred to as e.g. DTI (deep trench isolation) structure. The light blocking film 13 embedded in the opening is an insulating film or a metal film including e.g. tungsten. The light blocking film 13 may be a metal film including e.g. tin. The light blocking film 13 may be made of SiO₂ film, SiN film, or carbon.

To isolate the adjacent light reception sections 11, a p-type isolation layer may be provided between the light reception sections 11. In the case of providing a p-type isolation layer between the light reception sections 11, the light blocking film 13 may be formed in the isolation layer so as to be covered with the isolation layer. The isolation layer isolating the adjacent light reception sections 11 suppresses color mixing of photoelectrons between the pixel regions.

In the case of forming the light blocking film 13 from a conductive metal film, a silicon oxide film or the like is formed between the light reception section 11 (Si) and the light blocking film 13. The silicon oxide film functions as an insulating film. After forming the silicon oxide film or the like, a ground or negative voltage may be applied to the metal film. Holes are generated at the interface between the light reception section 11 (Si) and the light blocking film 13. This reduces the dark current.

The absorption coefficient of a material to light has wavelength dependence. For instance, in the case of using blue light of a wavelength of 400 nanometers, the absorption coefficient of Si is 8×10⁴ cm⁻¹. For instance, in the case of using red light of a wavelength of 700 nanometers, the absorption coefficient of Si is 2×10³ cm⁻¹. Si has a low absorption factor to red light having a longer wavelength than blue light. Si has a high absorption factor to blue light.

With regard to color mixing between the adjacent pixel regions, color mixing is not significant from a blue pixel region to the pixel region adjacent to the blue pixel region. Red light having a longer wavelength than blue light is received by the pixel region at a low absorption factor. Because of the low absorption factor, red light is not subjected to photoelectric conversion. The light incident on the light reception section 11 (pixel region) at an angle oblique to the direction from the second surface 10b toward the first surface 10a is incident on the adjacent light reception section 11 (pixel region). Color mixing may occur due to the light before photoelectric conversion.

The light blocking film 13 is formed between the adjacent light reception sections 11 (pixel regions). Then, the light incident on the light reception section 11 at an angle oblique to the direction from the second surface 10b toward the first surface 10a is reflected by the light blocking film 13. The light reflected by the light blocking film 13 is injected into the desired pixel region. The light blocking effect between the adjacent pixel regions can be improved by forming the light blocking film 13 between the adjacent light reception sections 11. This can suppress color mixing between the adjacent pixel regions.

The light blocking film 13 preferably includes a reflective material. The light blocking film 13 made of a reflective material can improve the sensitivity of the pixel.

The intermediate layer 12 is formed on the side surface and the bottom surface of the light blocking film 13. The intermediate layer 12 formed so as to enclose the side surface and the bottom surface of the light blocking film 13 can reduce the dark current. The intermediate layer 12 is e.g. a P-layer. After an opening is formed between the light reception sections 11 (pixel regions), boron or the like is implanted into the inner side surface of the opening by e.g. ion implantation or plasma doping. Thus, the intermediate layer 12 is formed on the inner side surface of the opening.

The intermediate layer 12 is formed on the inner side surface of the opening, and the light blocking film 13 is formed on the intermediate layer 12. Then, laser annealing is performed from the second surface 10b of the semiconductor layer 10 (the surface of the light blocking film 13). The implanted boron is activated, and the implantation defects of boron are repaired. The laser annealing is e.g. excimer laser annealing. Spike annealing or lamp annealing would heat the entirety of the semiconductor layer 10. Excimer laser annealing can heat the second surface 10b of the semiconductor layer 10 in the solid-state imaging device 110 of the back irradiation type. The solid-state imaging device 110 of the back irradiation type includes CMOS. Laser annealing does not significantly affect the characteristics of transistors and the wiring layer formed from Al or Cu.

The laser wavelength is e.g. 308 nanometers. The laser wavelength can be arbitrarily determined as long as it can be absorbed in the surface layer of the heated material. At a wavelength of 308 nanometers, the absorption depth of Si for laser light is approximately 7 nanometers.

The intermediate layer 12 is formed on the inner side surface of the opening, and the light blocking film 13 is formed on the intermediate layer 12. Then, laser irradiation is performed from the second surface 10b of the semiconductor layer 10 (the surface of the light blocking film 13). Such a method for manufacturing a solid-state imaging device provides a solid-state imaging device in which the decrease of sensitivity is small and the dark current is reduced.

In the following, experimental results led to the aforementioned conditions are described.

In the first to fourth experiments shown in FIGS. 6 to 9, in the solid-state imaging device 110, an opening is formed between the light reception sections 11 in the semiconductor layer 10. Boron is ion implanted into the inner side surface of the opening. Subsequently, laser irradiation is performed from the second surface 10b of the semiconductor layer 10. Then, a SiO₂ film is embedded as a light blocking film 13 in the opening. FIGS. 6 to 9 are reference views related to the solid-state imaging device 110 according to the second embodiment.

In the fifth experiment shown in FIG. 10, in the solid-state imaging device 110, an opening is formed between the light reception sections 11 in the semiconductor layer 10. Boron is ion implanted into the inner side surface of the opening. Subsequently, a SiO₂ film is embedded as a light blocking film 13 in the opening. Then, laser irradiation is performed from the second surface 10b of the semiconductor layer 10 (the surface of the light blocking film 13). FIG. 10 relates to the solid-state imaging device 110 according to the second embodiment.

### (First Experiment)

FIG. 6 is a reference diagram illustrating the relationship between the laser irradiation amount and the dark current.

In FIG. 6, the horizontal axis represents the laser irradiation amount Ir (J/cm²). The vertical axis represents the dark current Id (arbitrary unit).

FIG. 6 shows the relationship between the laser irradiation amount Ir and the dark current Id. The dark current Id decreases with the increase of the laser irradiation amount Ir.

### (Second Experiment)

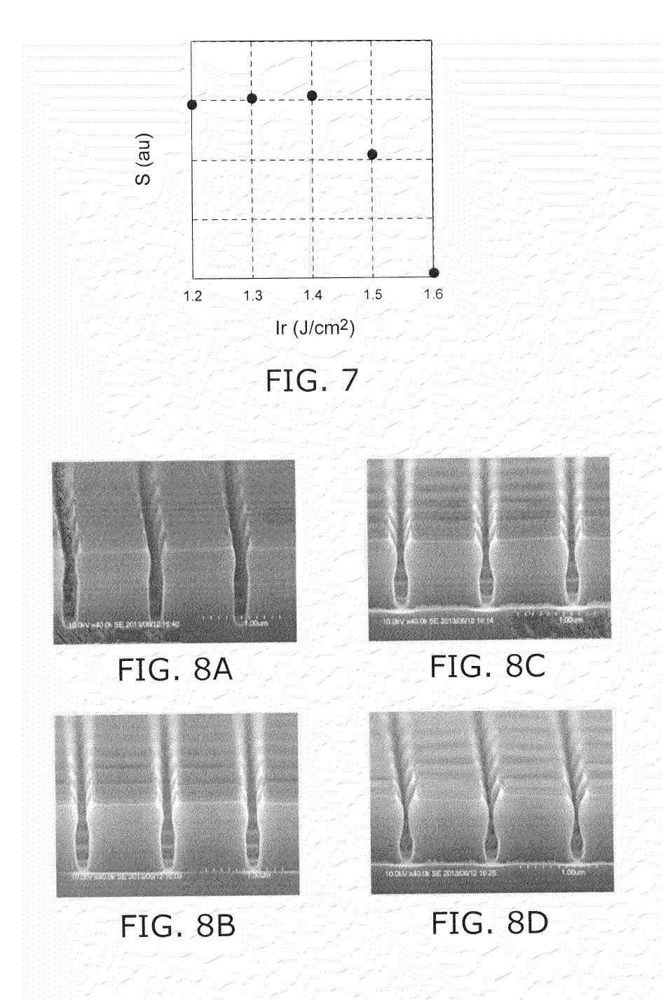

FIG. 7 is a reference diagram illustrating the relationship between the laser irradiation amount and the sensitivity.

In FIG. 7, the horizontal axis represents the laser irradiation amount Jr (J/cm²). The vertical axis represents the sensitivity S (arbitrary unit).

FIG. 7 shows the relationship between the laser irradiation amount Ir and the sensitivity S. The decreasing rate of the sensitivity S is small in the range of the laser irradiation amount Ir from 1.2 J/cm² to 1.4 J/cm². The sensitivity S significantly decreases when the laser irradiation amount Ir is 1.5 J/cm² or more. This significant decrease is attributable to the decrease of the amount of light incident on the pixel region due to the change of the shape of the sidewall by melting of Si formed on the sidewall of the DTI structure. The amount of light incident on the pixel region is decreased by the change of the feature of the pixel region. This significant decrease is attributable also to the fact that the width of the intermediate layer 12 formed on the sidewall of the DTI structure is widened in the direction from the front surface toward the bottom surface of the light blocking film 13.

### (Third Experiment)

FIGS. 8A to 8D are reference views illustrating the relationship between the laser irradiation amount and the DTI structure.

FIG. 8A shows the shape of the sidewall of the DTI structure in the case where the laser irradiation amount Ir is set to 1.2 J/cm². FIG. 8B shows the shape of the sidewall of the DTI structure in the case where the laser irradiation amount Ir is set to 1.3 J/cm². FIG. 8C shows the shape of the sidewall of the DTI structure in the case where the laser irradiation amount Ir is set to 1.4 J/cm². FIG. 8D shows the shape of the sidewall of the DTI structure in the case where the laser irradiation amount Ir is set to 1.5 J/cm².

FIGS. 8A to 8D show the relationship between the laser irradiation amount Ir and the shape of the sidewall of the DTI structure. At the time of laser irradiation, the light blocking film 13 is not formed inside the trench. With the increase of the laser irradiation amount Ir, Si formed on the sidewall melts to change the shape of the sidewall.

### (Fourth Experiment)

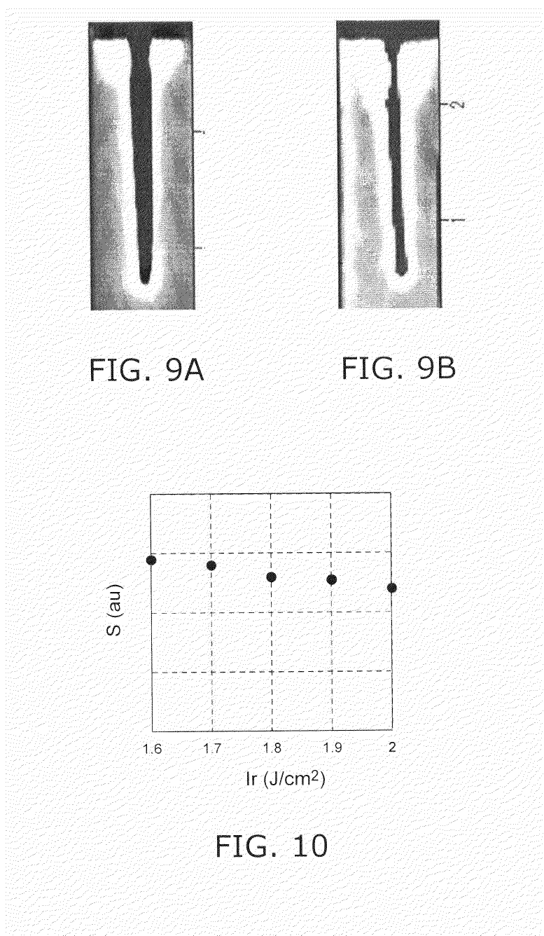

FIGS. 9A and 9B are reference views illustrating the relationship between the laser irradiation amount and the DTI structure.

An opening is formed between the light reception sections 11 in the semiconductor layer 10. Boron is ion implanted into the inner side surface of the opening. Laser irradiation is performed from the second surface 10b of the semiconductor layer 10. Then, a SiO₂ film is embedded as a light blocking film 13 in the opening. Subsequently, the feature of the DTI structure is observed by scanning spreading resistance microscopy.

Boron is activated because the second surface 10b of the semiconductor layer 10 is irradiated with laser. This decreases the resistance near the opening in the second surface 10b of the semiconductor layer 10.

As shown in FIG. 9A, in the case where the laser irradiation amount Ir is 1.2 J/cm², the width of the opening in the second surface 10b of the semiconductor layer 10 is wide. The width of the opening is narrowed in the direction from the second surface 10b toward the first surface 10a of the semiconductor layer 10. The amount of absorbed laser light decreases near the bottom surface of the DTI structure.

As shown in FIG. 9B, in the case where the laser irradiation amount Ir is 1.5 J/cm², the width of the opening in the second surface 10b of the semiconductor layer 10 is wide. Boron is activated also near the bottom surface of the DTI structure. The sidewall of the DTI structure is made convex by melting of Si.

The width of the intermediate layer 12 is widened in the direction from the second surface 10b toward the first surface 10a of the semiconductor layer 10 with the increase of the laser irradiation amount Ir. Then, the intermediate layer 12 does not affect the photoelectric conversion of incident light. The sensitivity decreases with the widening of the width of the intermediate layer 12.

### (Fifth Experiment)

FIG. 10 shows the relationship between the laser irradiation amount and the sensitivity in the second embodiment.

In FIG. 10, the horizontal axis represents the laser irradiation amount Ir (J/cm²). The vertical axis represents the sensitivity S (arbitrary unit).

As shown in FIG. 10, compared with FIG. 7, there is no significant decrease of the sensitivity from a particular laser irradiation amount Ir. The sensitivity gradually decreases with the increase of the laser irradiation amount Ir. The laser light is easily absorbed in Si of the light reception section 11. Thus, the sidewall of the DTI structure has a large absorption distribution of laser light. The width of the opening in the second surface 10b of the semiconductor layer 10 is widened.

In the DTI structure, the intermediate layer 12 is formed on the side surface and the bottom surface of the light blocking film 13. The second surface 10b of the semiconductor layer 10 is irradiated with laser. Then, the dark current is decreased. The SiO₂ film is embedded as a light blocking film 13 in the opening. This can suppress the sensitivity decrease due to the shape change of the sidewall of the DTI structure.

In this embodiment, the decrease of sensitivity is small, and the dark current can be reduced. Thus, this embodiment can provide a solid-state imaging device having improved display quality.

### Third Embodiment

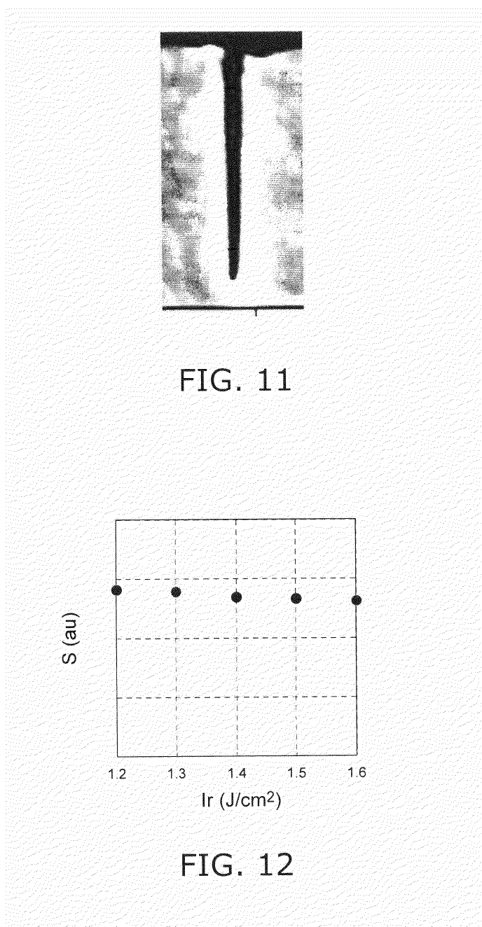

In the sixth and seventh experiments shown in FIGS. 11 and 12, in the solid-state imaging device 110, an opening is formed between the light reception sections 11 in the semiconductor layer 10. Boron is ion implanted into the inner side surface of the opening. After the ion implantation, a silicon oxide film is formed in the opening. A metal film including tungsten is embedded as a light blocking film 13. Subsequently, laser irradiation is performed from the second surface 10b of the semiconductor layer 10.

### (Sixth Experiment)

FIG. 11 illustrates the relationship between the laser irradiation amount and the DTI structure in a third embodiment.

In FIG. 11, the surface of the light blocking film 13 is irradiated with laser. Subsequently, the feature of the DTI structure is observed by scanning spreading resistance microscopy. The laser irradiation amount Ir is 1.6 J/cm².

The absorption depth of tungsten for light of a wavelength of 308 nanometers is approximately 10 nanometers. Heat is transferred by tungsten and activates boron implanted in the sidewall of the DTI structure. This repairs implantation defects. The laser light is not easily absorbed in the sidewall of the DTI structure. This relaxes the temperature distribution in the sidewall of the DTI structure. As the light blocking film 13, alternatively, a metal film including molybdenum, titanium, or tantalum may be embedded.

### (Seventh Experiment)

FIG. 12 illustrates the relationship between the laser irradiation amount and the sensitivity in the third embodiment.

In FIG. 12, the horizontal axis represents the laser irradiation amount Ir (J/cm²). The vertical axis represents the sensitivity S (arbitrary unit).

As shown in FIG. 12, there is no significant decrease of the sensitivity from a particular laser irradiation amount Ir. The sensitivity gradually decreases with the increase of the laser irradiation amount Ir. The decreasing rate of the sensitivity is small. The shape of the sidewall of the DTI structure does not change. Furthermore, the width of the intermediate layer 12 formed on the side surface of the light blocking film 13 is widened uniformly. Thus, the decreasing rate of the sensitivity is small.

In this embodiment, the decrease of sensitivity is small, and the dark current can be reduced. Thus, this embodiment can provide a solid-state imaging device having improved display quality.

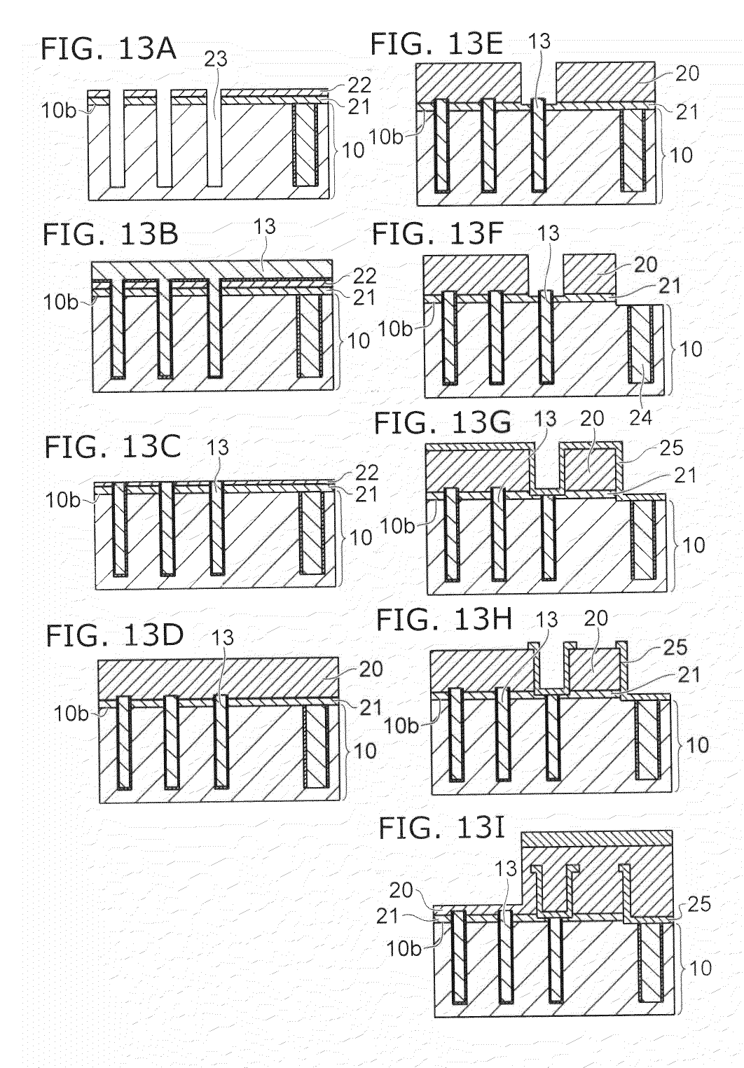

FIGS. 13A to 13I show a flow chart of part of a process for manufacturing a solid-state imaging device.

FIGS. 13A to 13I show a process for forming a DTI structure.

In FIG. 13A, an intermediate film 21 and an oxide film 22 are sequentially stacked as a hard mask on the second surface 10b of a semiconductor layer 10. The hard mask is used to form an opening 23 constituting a trench in the pixel region. The opening 23 is formed by etching technique including reactive ion etching.

The intermediate film 21 is e.g. a SiN film. The oxide film 22 is e.g. a SiO₂ film. The thickness of the SiN film is e.g. approximately 50 nanometers. The thickness of the SiO₂ film is e.g. approximately 200 nanometers.

In FIG. 13B, after the opening 23 is formed in the pixel region, boron or the like is ion implanted into the inner side surface of the opening. Subsequently, a SiO₂ film or the like is embedded as a light blocking film 13 in the opening. Then, laser irradiation is performed from the second surface 10b of the semiconductor layer 10.

In the case where the light blocking film 13 is a metal film, a silicon oxide film may be formed as an insulating film by ALD (atomic layer deposition) technique. Then, a TiN film may be formed as a barrier metal (barrier film). The thickness of the silicon oxide film is e.g. approximately 10 nanometers. The thickness of the TiN film is e.g. approximately 5 nanometers.

In FIG. 13C, the light blocking film 13 is planarized. The light blocking film 13 is planarized by e.g. CMP (chemical mechanical polishing) technique.

In FIG. 13D, an oxide film 20 is formed. The oxide film 20 is e.g. a SiO₂ film. The thickness of the oxide film 20 is e.g. approximately 300 nanometers.

In FIG. 13E, the light blocking film 13 is exposed on the second surface 10b. The light blocking film 13 is exposed by etching the oxide film 20 using etching technique including reactive ion etching.

In FIG. 13F, the trench 24 formed in the semiconductor layer 10 is exposed on the second surface 10b. The trench 24 is exposed by etching the oxide film 20 using etching technique including reactive ion etching.

In FIG. 13G, an overcoat film 25 is formed on the surface of the oxide film 20 and the exposed portion in the second surface 10b of the semiconductor layer 10. The overcoat film 25 is e.g. an Al film.

In FIG. 13H, part of the overcoat film 25 is removed. Part of the overcoat film 25 is removed by etching technique including reactive ion etching.

In FIG. 13I, the pixel region is exposed on the second surface 10b. The pixel region is exposed by etching the oxide film 20 using etching technique including dry etching. Subsequently, a color filter 50 and a microlens 60 are sequentially stacked.

The embodiments of the invention provide a laser heating treatment method and a method for manufacturing a solid-state imaging device in which an object is heated while suppressing the shape change of the object.

The embodiments of the invention have been described above with reference to examples. However, the invention is not limited to these examples. For instance, any specific configurations of various components such as the substrate, semiconductor layer, light reception section, intermediate layer, and light blocking film are encompassed within the scope of the invention as long as those skilled in the art can similarly practice the invention and achieve similar effects by suitably selecting such configurations from conventionally known ones.

Further, any two or more components of the specific examples may be combined within the extent of technical feasibility and are included in the scope of the invention to the extent that the purport of the invention is included.

Moreover, all laser heating treatment methods and methods for manufacturing the solid-state imaging device practicable by an appropriate design modification by one skilled in the art based on the laser heating treatment method and the method for manufacturing the solid-state imaging device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A laser heating treatment method comprising:
forming a film having a higher melting point than a structural body provided on a substrate so as to cover the structural body; and
heating the structural body by irradiating the film and the structural body with laser.

2. The method according to claim 1, wherein an unevenness is provided on a surface of the substrate.

3. The method according to claim 1, wherein the laser is an excimer laser.

4. The method according to claim 1, wherein transmittance of the film for a wavelength of the laser is higher than transmittance of the structural body for the wavelength.

5. The method according to claim 1, wherein the film includes at least one of SiO₂, Si₃N₄, and SiON.

6. The method according to claim 1, wherein the film includes Mo.

7. A method for manufacturing a solid-state imaging device, comprising:
forming a plurality of light reception sections in a semiconductor layer having a first surface and a second surface on opposite side from the first surface, and forming a depression from the second surface between the plurality of light reception sections;
forming an intermediate layer on an inner side surface of the depression; and
forming a light blocking film on the intermediate layer and performing irradiation with laser from the second surface.

8. The method according to claim 7, wherein the light blocking film has a higher melting point than the semiconductor layer.

9. The method according to claim 7, wherein the light blocking film includes at least one of SiO₂, Si₃N₄, and SiON.

10. The method according to claim 7, wherein the light blocking film includes at least one of molybdenum, tungsten, titanium, and tantalum.

11. The method according to claim 7, wherein light is incident on the plurality of light reception sections from the second surface.

12. The method according to claim 7, wherein the forming the intermediate layer includes ion implanting boron into the inner side surface of the depression.

13. The method according to claim 7, wherein the performing irradiation includes performing irradiation with excimer laser from the second surface.

14. A method for manufacturing a solid-state imaging device, comprising:
forming a plurality of light reception sections in a semiconductor layer having a first surface and a second surface on opposite side from the first surface, and forming a depression from the second surface between the plurality of light reception sections;
forming an intermediate layer on an inner side surface of the depression;
forming an insulating film on the intermediate layer; and
forming a light blocking film on the insulating film and performing irradiation with laser from the second surface.

15. The method according to claim 14, wherein the light blocking film has a higher melting point than the semiconductor layer.

16. The method according to claim 14, wherein the light blocking film includes at least one of molybdenum, tungsten, titanium, and tantalum.

17. The method according to claim 14, wherein the insulating film includes SiO₂.

18. The method according to claim 14, further comprising:
forming a barrier film between the insulating film and the light blocking film.

19. The method according to claim 14, wherein the forming the intermediate layer includes ion implanting boron into the inner side surface of the depression.

20. The method according to claim 14, wherein the performing irradiation includes performing irradiation with excimer laser from the second surface.
